(19) United States
(12) Patent Application Publication
(10) Pub. No.: US 2013/0327922 A1
(43) Pub. Date: Dec. 12, 2013

(54) IMAGE SENSOR WITH PIXEL-LEVEL AUTO LIGHT ATTENUATOR

(71) Applicant: NOVATEK MICROELECTRONICS CORP., Hsin-Chu (TW)

(72) Inventor: Shen-Fu Tsai, Taoyuan County (TW)

(73) Assignee: NOVATEK MICROELECTRONICS CORP., Hsin-Chu (TW)

(21) Appl. No.: 13/646,734

(22) Filed: Oct. 7, 2012

(30) Foreign Application Priority Data
Jun. 7, 2012 (TW) 101120477

(51) Int. Cl. H01L 27/146

(52) U.S. Cl. 250/208.1

(57) ABSTRACT

An image sensing device for sensing pixel data of a plurality of pixels in an image includes a substrate; a plurality of light sensing units, each of the plurality of light sensing units being formed in the substrate and corresponding to one of the plurality of pixels; and a plurality of pixel-level auto-light attenuators, each of the plurality of pixel-level light attenuators corresponding to one of the plurality of light sensing units. Each pixel-level light attenuator includes a transparent dielectric layer, formed on the corresponding light sensing unit; and an electronic-chromic layer, formed on the transparent dielectric layer.

### BACKGROUND OF THE INVENTION

1. Field of the Invention

The present invention relates to an image sensing device, and more particularly, to an image sensing device with pixel-level auto light attenuators capable of automatically adjusting the luminous flux emitted into the image sensing device.

2. Description of the Prior Art

Image sensing device are widely utilized in digital electronic products, such as scanners, digital cameras, mobile phones and personal digital assistants. The most common types of image sensing device are Complementary Metal Oxide Semiconductors (CMOS) and Charge Coupled Device (CCD). These image sensing device are both silicon semiconductor devices utilized for sensing light and transferring the sensed light into electricity. The electricity generated by the image sensing device is transferred into measureable voltages, from which digital data can be acquired.

Please refer to FIG. 1, which is a characteristic diagram of the luminous flux received by a conventional image sensing device and the voltage generated by the conventional image sensing device. The voltage corresponds to the image information sensed by the image sensing device. As shown in FIG. 1, the image sensing device transfers the luminous flux to a measureable voltage once the luminous flux received by the image sensing device exceeds a minimum luminous flux LFmin. In other words, the image sensing device acquires valid image information when the luminous flux received by the image sensing device during an image sensing time period exceeds the minimum luminous flux LFmin. Thus, if the minimum luminous flux is made smaller, the image sensing device may acquire image information corresponding to less luminance.

The image sensing generates a maximum voltage Vmax when the luminous flux received by the image sensing device exceeds a maximum luminous flux LFmax. In other words, the image sensing device outputs maximum voltage Vmax when different image information having corresponding luminous flux exceeding the maximum luminous flux LFmax are received by the image sensing device. In such a condition, the different image information cannot be identified. Therefore, when the maximum luminous flux LFmax becomes higher, the luminous flux range of the image information which can be identified by the image sensing device becomes broader. The prior art provides a dynamic range (DR) as an indicator for evaluating the luminous flux range of the image information which is capable of being identified by the image sensing device, i.e. the range of the luminous flux which is received by the image sensing device and is capable of being identified by the image sensing device. The dynamic range is defined as:

$$DR = 20 Log ( \frac{LF max}{LF min} )$$

When the dynamic range of the image sensing device is increased, the luminous flux differences in the image information which can be sensed by the image sensing device become greater.

Please refer to FIG. 2, which is a schematic diagram of simulation results measured when the conventional image sensing device receives light of different luminance. The curves C1-C3 respectively correspond to the lights L1-L3 of different luminance. As shown in FIG. 2, the luminous flux generated by the light L1 per unit time is greatest, and its respective curve C1 reaches a maximum charge Qmax (corresponding to the maximum voltage Vmax and the maximum luminous flux LFmax) at a time T1. The luminous flux generated by the light L3 per unit time is smallest, and its curve C3 does not reach a minimum charge Qmin (corresponding to the minimum luminous flux LFmin) at the time T1. In such a condition, if the exposure time of the image sensing device is set to be time T1, the image sensing device cannot generate enough charge to acquire the image information of the light L3. Thus, the exposure time of the image sensing device has to be extended for acquiring image information with low luminance. If, however, the exposure time of the image sensing device is extended to a time T2 for allowing the curve C3 to exceed the minimum charge Qmin, both the curves C1 and C2 will exceed the maximum charge Qmax, such that the image sensing device cannot identify the difference between the image information of the lights L1 and L2.

As can be seen from the above, the dynamic range of the conventional image sensing device has limitations resulting in the image sensing device being unable to acquire image information with a wide rage of luminance at a time of image sensing. A conventional method for increasing the dynamic range of the image sensing device is to adapt multiple exposures. The multiple exposures need to acquire image information with different ranges of luminance at multiple times to achieve an image sensing time. As a result, the multiple exposures method not only wastes time, but also cannot be applied to an image with a subject which is moving at high speed.

### SUMMARY OF THE INVENTION

Therefore, an image sensing device having pixel-level auto light attenuators is disclosed, capable of automatically adjusting the luminous flux emitted into the image sensing device according to the voltage corresponding to the pixel data, for effectively increasing the dynamic range of the image sensing device.

In an aspect, an image sensing device is disclosed, for sensing pixel data of a plurality of pixels in an image. The image sensing device comprises a substrate; a plurality of light sensing units, each of the plurality of light sensing units being formed in the substrate and corresponding to one of the plurality of pixels; and a plurality of pixel-level auto-light attenuators, each of the plurality of pixel-level light attenuators corresponding to one of the plurality of light sensing units and comprising a transparent dielectric layer, formed on the corresponding light sensing unit; and an electronic-chromic layer, formed on the transparent dielectric layer.

In another aspect, an image sensing device is disclosed, for sensing pixel data of a plurality of pixels in an image. The image sensing device comprises a substrate; a plurality of light sensing units, each of the plurality of light sensing units being buried in the substrate and corresponding to one of the plurality of pixels; and a plurality of pixel-level auto light attenuators, each of the plurality of pixel-level auto light attenuators corresponding to one of the plurality of light sensing units and comprising a switch, coupled between the corresponding light sensing unit and a reset voltage; and a doped layer, formed on the corresponding light sensing unit and doped with electronic-chromic materials.

In another aspect, an image sensing device is disclosed for sensing pixel data of a plurality of pixels in an image. The image sensing device comprises a substrate; a plurality of light sensing units, each of the plurality of light sensing units being formed in the substrate and corresponding to one of the plurality of pixels; and a plurality of pixel-level auto light attenuators, each of the plurality of pixel-level auto light attenuators comprising a micro-electro-mechanical (MEM) unit, formed on the corresponding light sensing unit, for adjusting the luminous flux emitted into the corresponding light sensing unit.

In another aspect, an image sensing device is disclosed for sensing pixel data of a plurality of pixels in an image. The image sensing device comprises a substrate; a plurality of light sensing units, each of the plurality of light sensing units being formed in the substrate and corresponding to one of the plurality of pixels; and a plurality of pixel-level auto-light attenuators, each of the plurality of pixel-level light attenuators corresponding to one of the plurality of light sensing units for automatically adjusting the luminous flux emitted into the corresponding light sensing unit according to an electric field generated by the voltage of the corresponding light sensing unit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a characteristic diagram of the luminous flux received by a conventional image sensing device and the voltage generated by the conventional image sensing device.

FIG. 2 is a schematic diagram of simulation results measured when the conventional image sensing device receives lights of different luminance.

FIG. 3A is a schematic diagram of an image sensing device according to an embodiment of the present invention.

FIG. 3B is a schematic diagram of a light sensing unit and a pixel-level auto light attenuator of the image sensing device shown in FIG. 3A.

FIG. 4A and FIG. 4B are schematic diagrams of the operating procedures of the image sensing device shown in FIG. 3B.

FIG. 5 is a characteristic diagram of the luminous flux received by the image sensing device shown in FIG. 3B and the voltage generated by the image sensing device shown in FIG. 3B.

FIG. 6 is a schematic diagram of simulation results measured when the image sensing device shown in FIG. 3B receives lights of different luminance.

FIG. 7 is a schematic diagram of another image sensing device according to an embodiment of the present invention.

FIG. 8 is a voltage distribution diagram of the operating procedure of the image sensing device shown in FIG. 7.

FIG. 9 is a schematic diagram of another implementation method of the image sensing device shown in FIG. 3B.

FIG. 10 is a schematic diagram of an implementation method of a micro-electro-mechanical unit according to the image sensing device shown in FIG. 9.

FIGS. 11A-11C are cross-sectional views of the operating procedure of the image sensing device shown in FIG. 9 according to an embodiment.

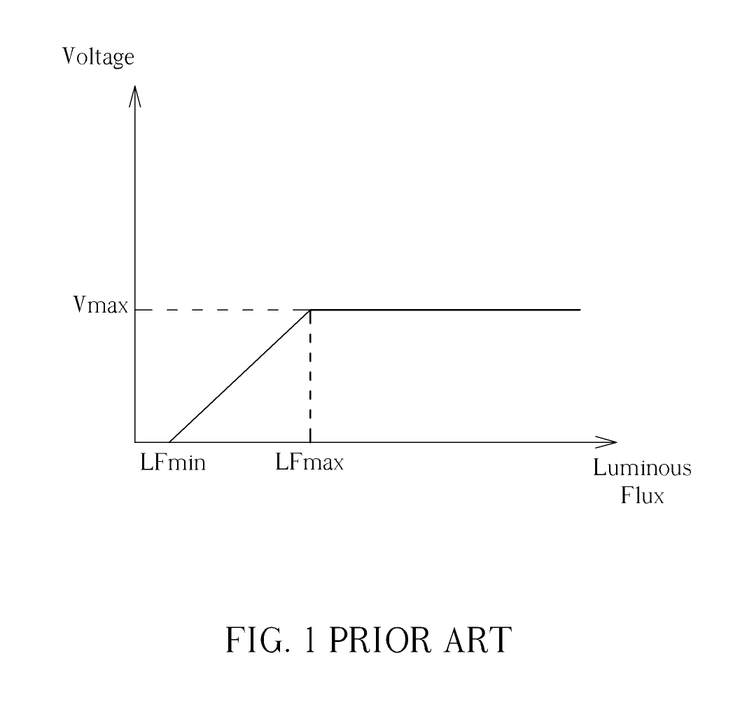

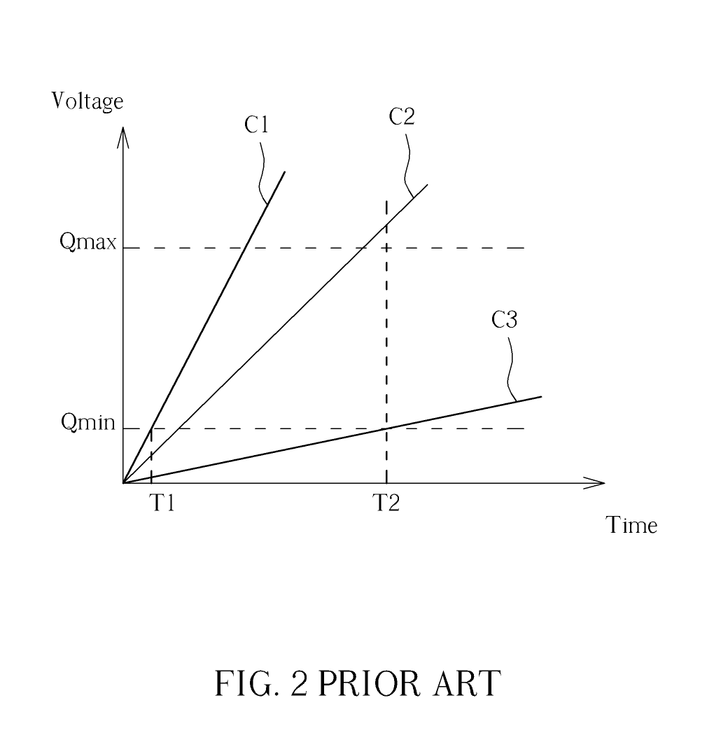

### DETAILED DESCRIPTION

In the following embodiments of the present invention, image sensing devices comprising a plurality of pixel-level auto light attenuators are disclosed. Each pixel-level auto light attenuator adjusts the luminous flux received by a pixel according to a voltage corresponding to the pixel data of the pixel. Accordingly, the image sensing device adjusts ratios of the luminous flux received by light sensing elements of the pixel when the pixel receives a certain amount of the luminous flux, such that the dynamical range of the image sensing device can be increased. The present invention is particularly shown and described with respect to at least one exemplary embodiment accompanied by drawings. Words utilized for describing connections between two components such as ‘couple’ and ‘connect’ should not be taken as limiting a connection between the two components to be directly coupling or indirectly coupling.

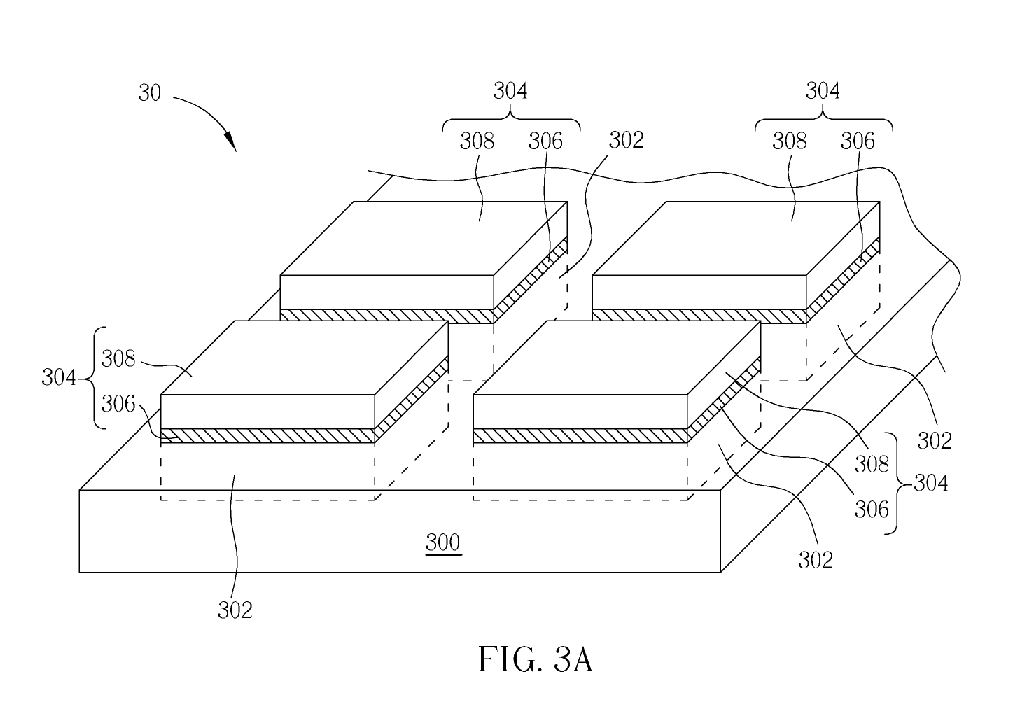

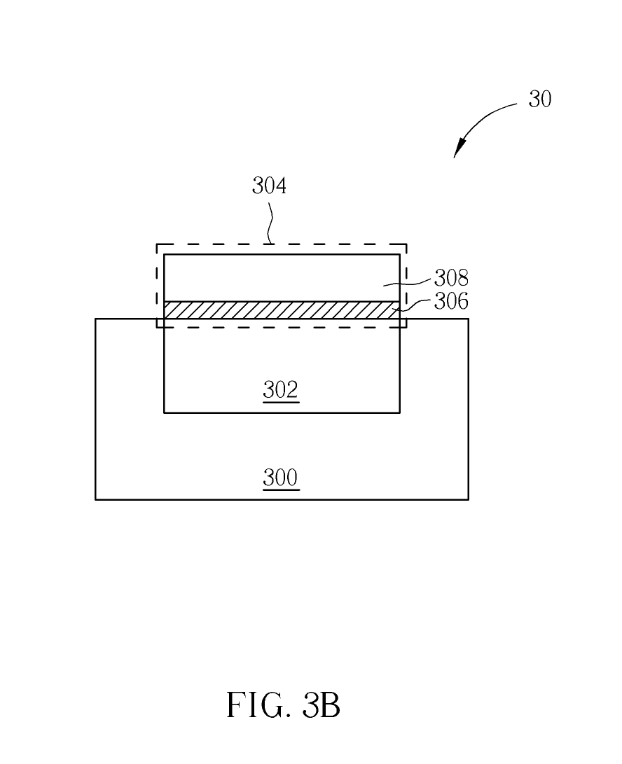

Please refer to FIG. 3A, which is a schematic diagram of an image sensing device 30 according to an embodiment of the present invention. The image sensing device 30 is utilized for sensing pixel data of a plurality of pixels in an image data. In brief, a substrate 300, a plurality of light sensing units 302 and a plurality of pixel-level auto light attenuators 304 of the image sensing device 30 are shown in FIG. 3A, wherein subsequent circuitry, such as circuitry for converting pixel data and image processing circuitry, are not shown in FIG. 3A for brevity. Furthermore, following explanations focus on a light sensing unit 302 and the corresponding pixel-level auto light attenuator 304 for simplicity. Please refer to FIG. 3B, which is a schematic diagram of a light sensing unit 302 and the corresponding pixel-level auto light attenuator 304. As shown in FIG. 3B, the substrate 300 is a first type substrate (e.g. a P-substrate). The light sensing unit 302 is formed in a second type (e.g. an N-type) photodiode area. The light sensing unit 302 receives the luminous flux generated by the emitted light and accordingly generates a voltage VS corresponding to pixel data of a pixel. The pixel-level auto light attenuator 304 comprises a transparent dielectric layer 306 and an electro-chromic layer 308. The pixel-level auto light attenuator 304 adjusts the luminous flux emitted to the light sensing unit 302 according to the voltage VS generated by the light sensing unit 302, to increase the dynamic range of the image sensing device 30. Please note that each light sensing unit 302 corresponds to a pixel level auto light attenuator 304 in the embodiment shown in FIG. 3A. In other embodiments, the image sensing device 30 may also comprise a plurality of light sensing units 302 and a plurality of pixel-level auto light attenuators 304, and the multiple (e.g. two or three) light sensing units 302 jointly correspond to a pixel-level auto light attenuator 304.

In detail, the transparent dielectric layer 306 may be an insulation material formed on the light sensing unit 302. For example, the transparent dielectric layer 306 is printed on the light sensing unit 302, but the embodiment is not limited therein. In addition, the transparent dielectric layer 306 is light penetrating and the transparency of the transparent dielectric layer 306 is determined according to design requirements. In preferred embodiments, the transparent dielectric layer 306 is completely transparent or substantially transparent. In other embodiments, the transparent dielectric layer 306 can be partially transparent. The electro-chromic layer 308 is formed by electro-chromic materials. The transparency of the electro-chromic layer 308 is determined according to an electric field E passing through the electro-chromic layer 308. When the intensity of the electric field E is zero (i.e. the voltage VS is the ground voltage), the transparency of the electro-chromic layer 308 (corresponding to the luminous flux received by the light sensing unit 302 per unit time) may be configured to be at its highest. When the light sensing unit 302 receives the luminous flux and generates the voltage VS, the intensity of the electric field E is increased via the electrostatic induction, such that the transparency of the electro-chromic layer 308 is decreased for reducing the luminous flux emitted into the light sensing unit 302. In other words, via the electrostatic induction, the relationship between the intensity of the electric field E and the absolute value of the voltage VS is positively correlated (e.g. the intensity of the electric field E is directly proportional to the absolute value of the voltage VS) and the relationship between the transparency of the electro-chromic layer 308 and the intensity of the electric field E is negatively correlated (e.g. the transparency of the electro-chromic layer 308 is inversely proportional to the intensity of the electric field E). Thus, the electro-chromic layer 308 automatically decreases the luminous flux emitted into the light sensing unit 302 when the luminous flux received by the light sensing unit 302 increases, such that the dynamic range of the image sensing device 30 is enlarged.

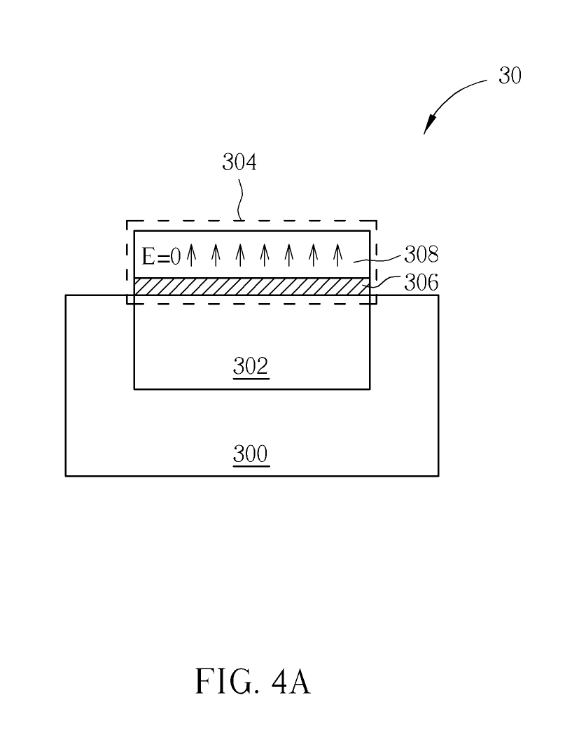

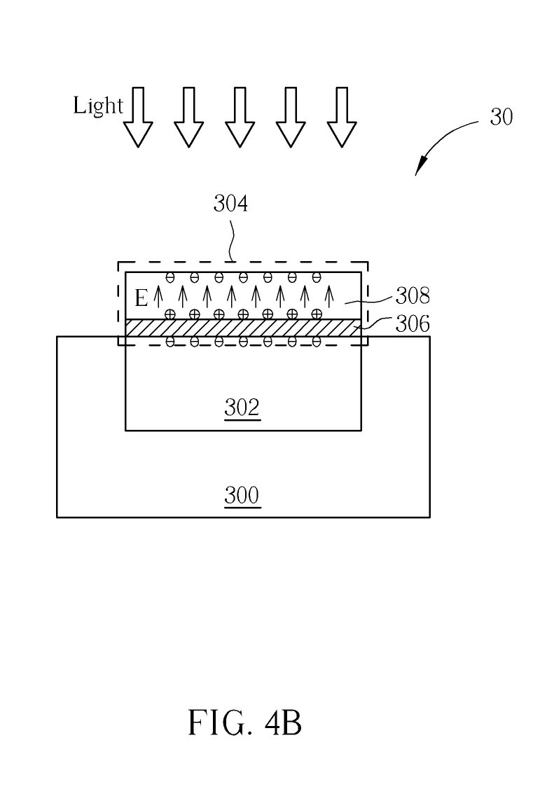

Please refer to FIG. 4A and FIG. 4B, which are exemplary schematic diagrams of the operating procedures of the image sensing device 30 shown in FIG. 3B. As shown in FIG. 4A, when the light sensing device 302 does not receive the luminous flux and does not generate the voltage VS, there is no electric field in the electro-chromic layer 308 and the transparency of electro-chromic layer 308 is the highest. Next, please refer to FIG. 4B, when the light sensing unit 302 begins to receive the luminous flux and to generate the voltage VS on a surface coupled to the transparent dielectric layer 306. Via the electrostatic induction, holes are generated on a surface of the electro-chromic layer 308 coupled to the transparent dielectric layer 306 (i.e. the bottom area of the electro-chromic layer 308). The electrons of the electro-chromic layer 308 are concentrated to the top area of the electro-chromic layer 308. As a result, the electric field E is generated in the electro-chromic layer 308 and the transparency of the electro-chromic layer is accordingly changed. The voltage VS is decreased with the accumulation of the luminous flux received by the light sensing unit 302, such that the intensity of the electric field E is gradually increased and the transparency of the electro-chromic layer 308 is decreased. Thus, the electro-chromic layer 308 reduces the luminous flux emitted into the light sensing unit 302 when the absolute value of the voltage VS generated by the light sensing unit 302 is increased. The above mentioned operating procedures is achieved during a time of image sensing, i.e. the image sensing device 30 acquires the image information with high dynamic range during a time of image sensing.

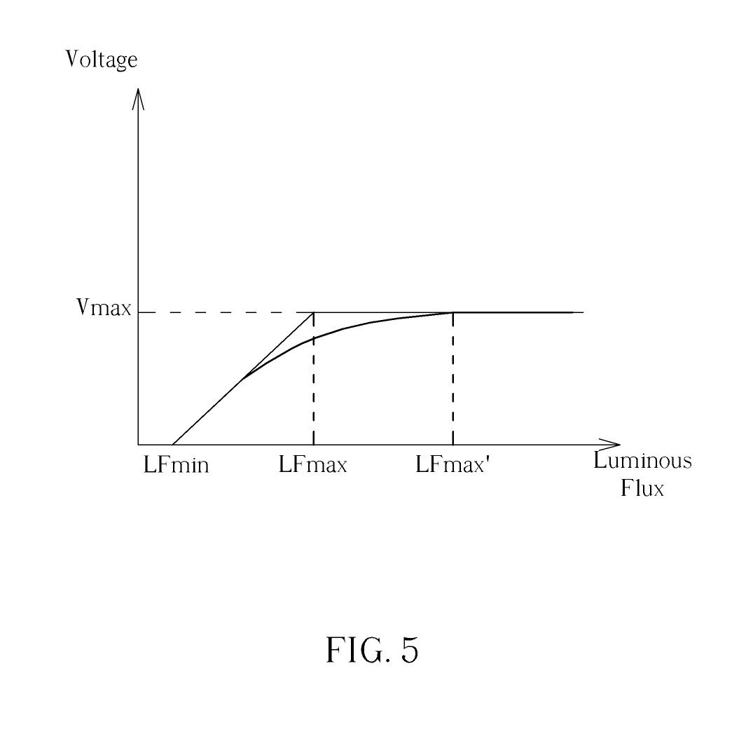

Please refer to FIG. 5, which is an exemplary characteristic diagram showing the relationship between the voltage VS and the luminous flux received by the image sensing device 30. As shown in FIG. 5, the slope of the characteristic curve is substantially the same in the low luminance area (i.e. low luminous flux) Thus the image sensing device 30 maintains the same sensitivity of the image information with low luminance. Since the transparency of the electro-chromic layer 308 is decreased when the voltage VS is increased, the slope of the characteristic curve becomes smaller when the voltage VS becomes greater. The luminous flux corresponding to the maximum voltage Vmax is changed from the maximum luminous flux LFmax to a greater maximum luminous flux LFmax′; thus, the image sensing device 30 increases the sensitivity of the image information with high luminance. The dynamic range of the image sensing device 30 can be defined as:

$$DR = 20 Log ( \frac{LF {max}^{′}}{LF min} )$$

In this way, the pixel-level auto light attenuator 304 enlarges the dynamic range of the image sensing device 30.

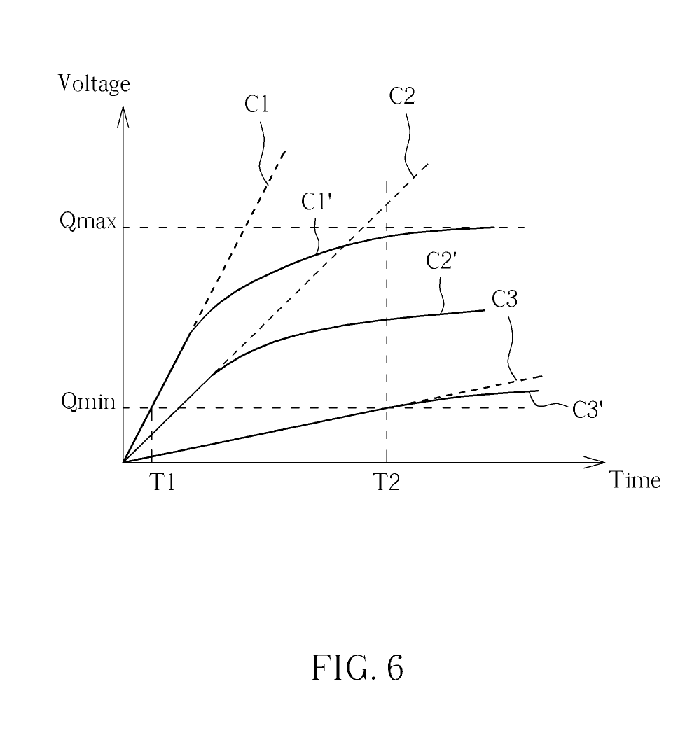

Similarly, the extension of the dynamic range of the image sensing device 30 can also be observed from the characteristic curves generated by illuminating the image sensing device 30 shown in FIG. 3B with lights of different luminance. Please refer to FIG. 6, which is a schematic diagram of simulation results measured when the image sensing device 30 receives lights of different luminance. The curves C1-C3 represented by dashed lines and the curves C1′-C3′ represented by solid lines correspond to the lights L1-L3 having different luminance, respectively. The curves C1-C3 correspond to the conventional image sensing device and the curves C1′-C3′ correspond to the image sensing device 30 of the embodiment of the present invention. As shown in FIG. 6, since the transparency of the electro-chromic layer 308 is decreased with the accumulation of the received luminous flux, the rate of the light sensing unit 302 generating electrons is also decreased, such that the slope of the curve C1′ becomes smaller with the accumulation of the received luminous flux. Similarly, the slopes of the curves C2′ and C3′ also change with the accumulation of the received luminous flux. Different from the conventional image sensing device, the curve C3′ reaches the minimum charge Qmin and the curves C1′ and C2′ do not saturate to the maximum charge Qmax when the exposure time is set to the time T2. Thus, the image sensing device 30 enlarges the luminance range of identifiable image information, i.e. the dynamic range of the image sensing device 30 is effectively increased.

Please note that the main spirit of the above embodiments is utilizing the plurality of pixel-level auto light attenuators for automatically adjusting the ratio of the luminous flux received by each light sensing unit of the image sensing device according to the voltage generated by each light sensing unit which receives luminous flux. This allows the goal of increasing dynamic range of the image sensing device to be achieved. Instead of sensing image information with different luminance ranges in multiple times, the above embodiment can acquire image information with a high dynamic range during an image sensing procedure time. Since the above embodiments can automatically adjust the ratio of the luminous flux received by each light sensing unit of the image sensing device according to the voltage generated by each light sensing unit receiving the luminous flux, the above embodiments adjust the ratio of the luminous flux corresponding to each pixel rather than jointly adjusting the ratio of the luminous flux corresponding to multiple pixels. As a result, a more precise adjustment can be achieved.

Those skilled in the art may observe appropriate alternations or modifications according to different applications. For example, the transparent dielectric layer 306 of the image sensing device 30 can be replaced by a filter corresponding to a specific color, such that the image sensing unit 302 receives the luminous flux corresponding to the specific color. Alternatively, the image sensing device 30 may further comprise a filter corresponding to a specific color. The filter is formed on the electro-chromic layer 308. As a result, the light sensing unit 302 also receives the luminous flux corresponding to the specific color. Preferably, the filter is printed on the electro-chromic layer 308, but the embodiment is not limited therein.

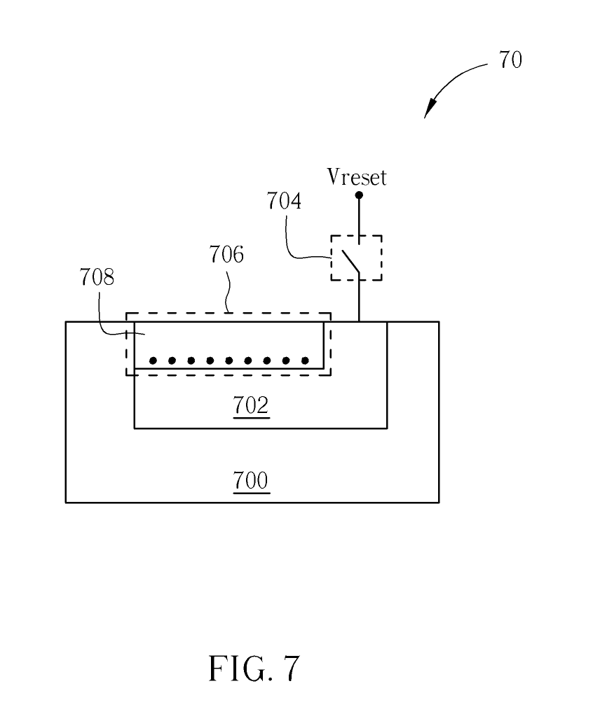

The image sensing device 30 can be realized in other structures. Please refer to FIG. 7, which is a schematic diagram of an image sensing device 70 according to an embodiment of the present invention. The image sensing device is utilized for sensing a pixel data of an image. As shown in FIG. 7, the image sensing device 70 comprises a substrate 700, a light sensing unit 702, a switch 704 and a pixel-level auto light attenuator 706. Similar to the image sensing device 30, the substrate 700 is a first type substrate (e.g. a P-substrate). The light sensing unit 702 is formed in a second type (e.g. an N-type) photodiode area. Different from the image sensing device 30, the light sensing device 702 is buried in the substrate 700 and is coupled to the switch 704. The switch 704 is coupled to the light sensing unit 702 and a reset voltage Vreset, for controlling a connection between the light sensing unit 702 and the reset voltage Vreset. The pixel-level auto light attenuator 706 comprises a doped layer 708. The dope layer 708 adjusts the luminous flux emitted into the light sensing unit 702, for increasing the dynamic range of the image sensing device 70. The image sensing device 70 may comprise a plurality of light sensing units 702 being buried in the substrate 700, a plurality of switches 704 and a plurality of pixel-level auto light attenuators as the image sensing device 30 shown in FIG. 3A, for receiving pixel data corresponding to a plurality of pixels of a complete image, but is not limited therein.

Before the image sensing device 70 starts to sense an image, the switch 704 is conductive for resetting the voltage of the light sensing unit 702 to the reset voltage Vreset. In this embodiment, the reset voltage Vreset is a positive voltage but is not limited thereto. A voltage difference between the light sensing unit 702 and the surface of the substrate 700 becomes the voltage Vreset, such that an electric field E is formed and passes through the doped layer 708. Since the doped layer 708 is a doped area doped with electro-chromic materials, the transparency of the doped layer 708 changes with the intensity of the electric field E. In this embodiment, the intensity of the electric field E is the maximum when the voltage of the light sensing unit 702 is the reset voltage Vreset and the transparency of the doped layer 708 is also maximized. Next, the switch 704 is disconnected when the image sensing device 70 starts to sense the image. The light sensing unit 702 begins to receive the luminous flux and to generate electrons, and then the voltage of the light sensing unit 702 starts to be decreased from the reset voltage Vreset. Thus, both the intensity of the electric field E and the transparency of the doped layer 708 will be gradually decreased when the light sensing unit 702 starts to receive the luminous flux. Accordingly, the doped layer 708 automatically reduces the luminous flux emitted into the light sensing unit when the luminous flux received by the light sensing unit 702 is accumulated.

Please note that the electro-chromic material doped in the doped layer 708 can be trivalent electronic-chromic materials or other electro-chromic materials. If the doped electro-chromic materials are not trivalent electronic-chromic materials, the doped density cannot be too high otherwise the characteristic of the doped area may be changed.

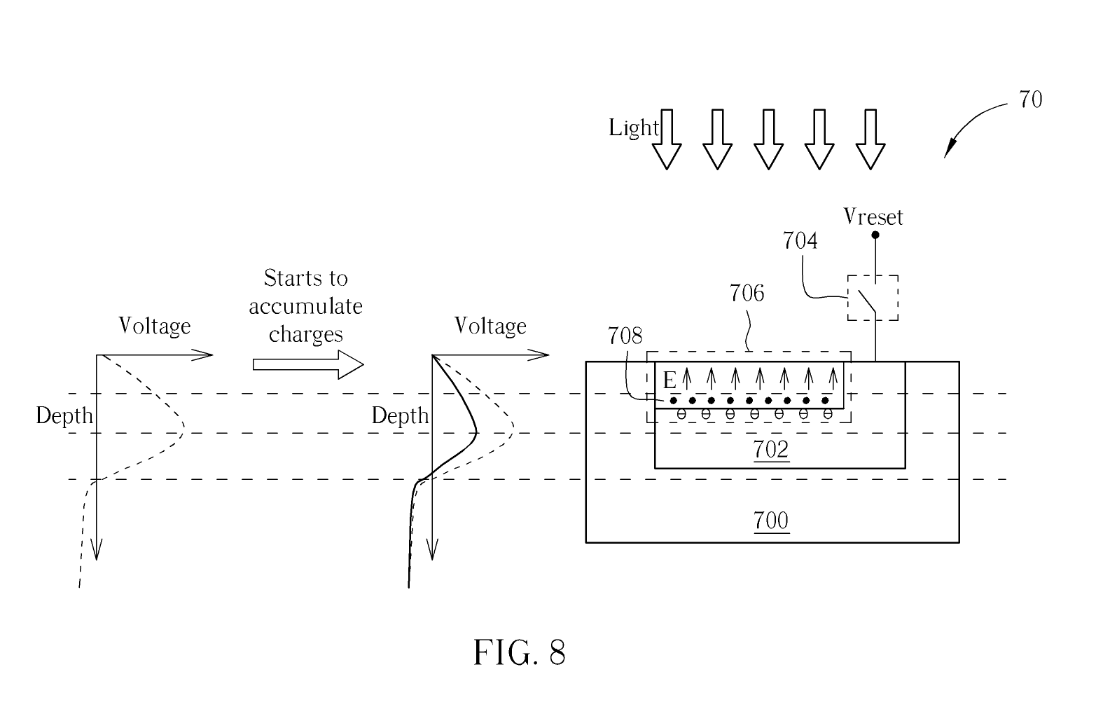

Please refer to FIG. 8, which is an exemplary voltage distribution diagram of the operating procedures of the image sensing device 70. As shown in FIG. 8, the image sensing device 70 conducts the switch 704 for resetting the voltage of the light sensing unit 702 to the reset voltage Vreset. The voltage difference between the light sensing unit 702 and the surface of the substrate 700 is the reset voltage Vreset, such that the electric field E is generated and the transparency of the doped layer 708 is maximized. After the light sensing unit 702 receives the luminous flux, the voltage of the light sensing unit 702 is gradually decreased from the reset voltage Vreset. Thus, both the voltage difference between the light sensing unit 702 and the surface of the substrate 700 and the intensity of the electric field E are decreased, such that the transparency of the doped layer 708 is reduced.

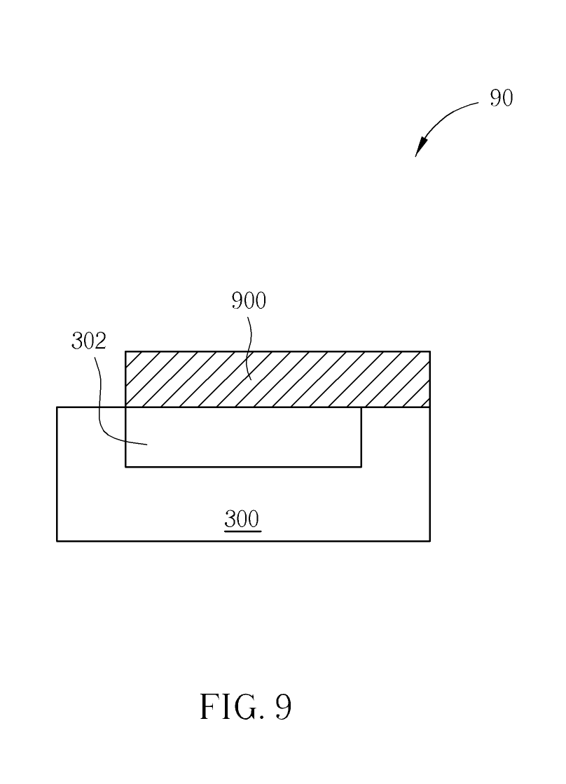

The pixel-level auto light attenuator 304 of the image sensing device 30 can be realized by micro-electro-mechanical (MEM) devices. Please refer to FIG. 9, which is a schematic diagram of another implementation method of the image sensing device 30 shown in FIG. 3B according to an embodiment of the present invention. Different from the image sensing device 30 shown in FIG. 3B, the pixel-level auto light attenuator 304 is realized in a micro-electro-mechanical unit 900. The structure of the micro-electro-mechanical unit 900 is similar to a shutter, which automatically adjusts the luminous flux emitted to the light sensing unit 302 according to the voltage VS generated by the light sensing unit 302 receiving the luminous flux, for enlarging the dynamic range of the image sensing device 30.

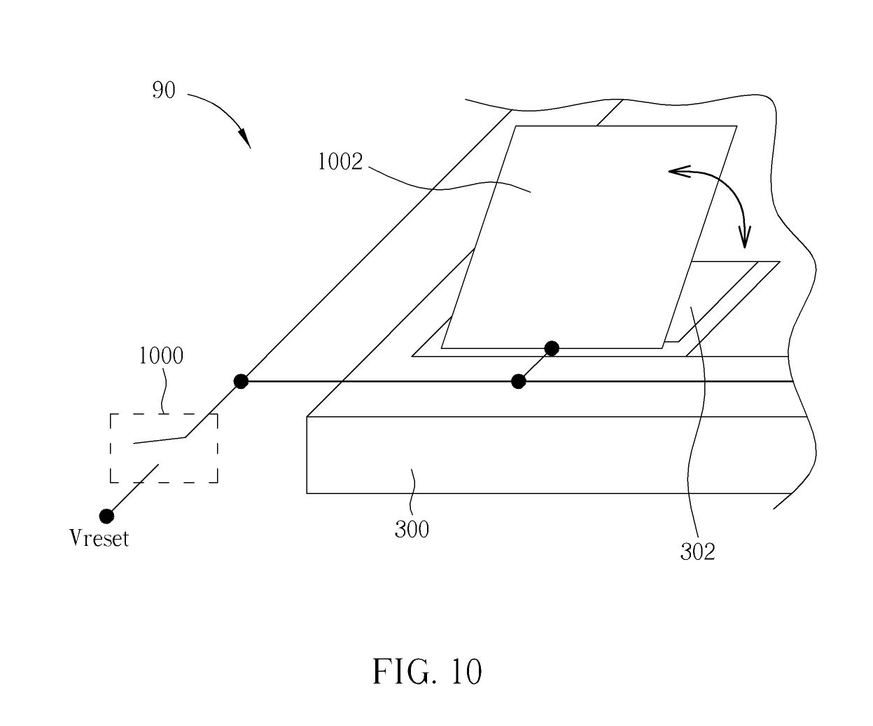

The image sensing device 90 shown in FIG. 9 is an exemplary embodiment of the present invention and utilizes a block diagram to explain one concept of the present invention. Therefore, the methods of each block and the generating methods of the related signals can be modified according to various system demands. For an illustration of one of these methods, please refer to FIG. 10, which is a schematic diagram of an implementation method of the micro-electro-mechanical unit 900 in the image sensing device 90 according to an embodiment of the present invention. As shown in FIG. 10, the micro-electro-mechanical unit 900 comprises a switch 1000 and a conductive flexible membrane 1002. The switch 100 is coupled to a reset voltage Vreset at a first end and is coupled to the conductive flexible membrane 1002 and the light sensing unit 302 at a second end. The conductive flexible membrane 1002 can be an opaque conductive flexible membrane covering the light sensing unit 302. A side of the conductive flexible membrane 1002 is fixed on the light sensing unit 302. In an embodiment, the conductive flexible membrane 1002 is a gold membrane formed on the light sensing unit 302 with a deposition (sputtering) method. Since the conductive flexible membrane 1002 is partially fixed on the substrate, the angle between the conductive flexible membrane 1002 and the light sensing unit 302 may be changed according to the voltage VS generated by the light sensing unit 302. Thus, the conductive flexible membrane 1002 can adjust the luminous flux emitted into the light sensing unit 302 according to the voltage VS, for enlarging the dynamic range of the image sensing device 90. Please note that the embodiment utilizes a micro-electro-mechanical unit with a conductive flexible membrane and a switch for explanation. In other embodiments, the micro-electro-mechanical unit may comprise a plurality of conductive flexible membranes and a plurality of switches. Moreover, the shape of the conductive flexible membrane shown in FIG. 10 is substantially a rectangle, but the shape of the conductive flexible membrane may be other shapes according to different design requirements.

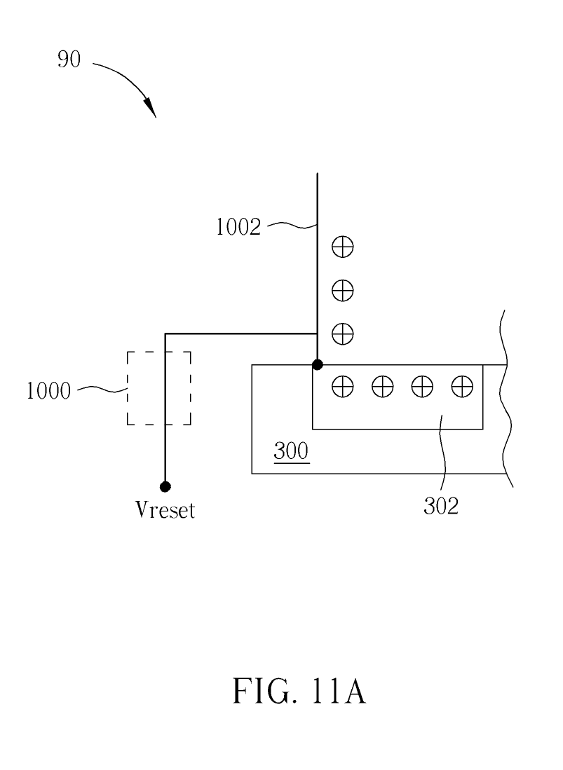

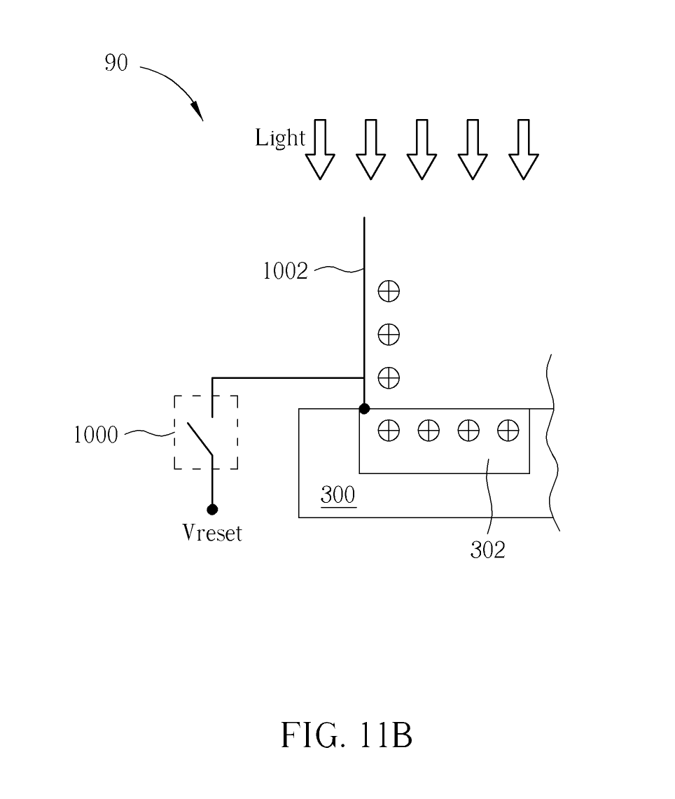

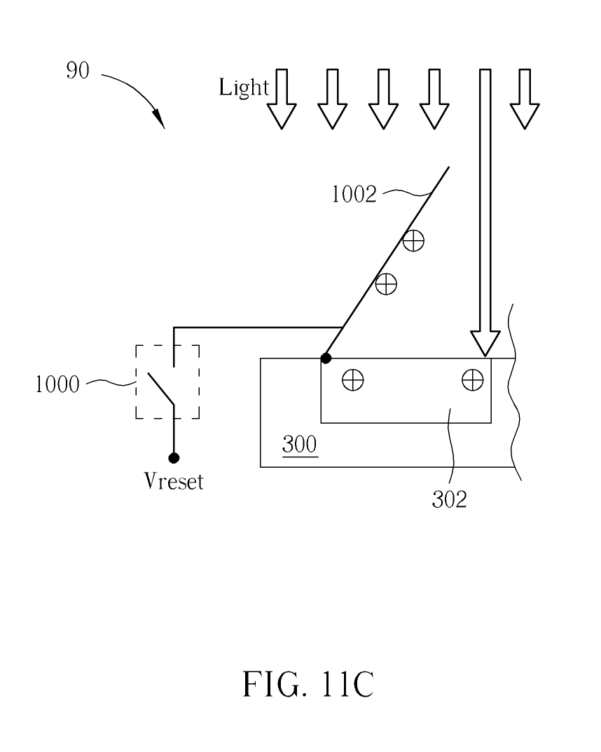

Please refer to FIGS. 11A-11C, which are schematic diagrams of cross-sectional views of the image sensing device 90 shown in FIG. 10. As shown in FIG. 11A, the image sensing device 90 first conducts the switch 1000 before receiving the pixel data, for resetting the voltages of the conductive flexible membrane 1002 and the light sensing unit 302 to the reset voltage Vreset. In this embodiment, the reset voltage Vreset is a positive voltage but is not limited thereto. The conductive flexible membrane 1002 and the light sensing unit 302 are perpendicular to each other via electrostatic repulsion. Please refer to FIG. 11B, which illustrates that the switch 1000 is disconnected when the image sensing device starts to receive pixel data. In such a condition, the light sensing unit completely receives the luminous flux of the emitted light without being blocked by the conductive flexible membrane 1002. Finally, please refer to FIG. 11C, which illustrates that the voltages of the conductive flexible membrane 1002 and the light sensing unit 302 are gradually decreased as the light sensing unit 302 receives the luminous flux and generates electrons. Thus, the electrostatic repulsion between the conductive flexible membrane 1002 and the light sensing unit 302 becomes weaker, and the angle between the conductive flexible membrane 1002 and the light sensing unit 302 becomes smaller. As a result, part of the emitted light is blocked by the conductive flexible membrane 1002 and the luminous flux emitted into the light sensing unit 302 is reduced. As can be seen from the above, via the electrostatic induction, the conductive flexible membrane 1002 automatically reduces the luminous flux emitted into the light sensing unit 302 when the luminous flux received by the light sensing unit 302 is increased. In this way, the dynamic range of the light sensing device 90 is enlarged.

To sum up, the image sensing devices disclosed by the above embodiments utilize pixel-level auto light attenuators realized utilizing different methods to adjust the luminous flux emitted into the light sensing unit according to the voltage generated by the light sensing unit, such that the dynamic range of the image sensing device is enlarged. Accordingly, instead of adjusting the luminous flux emitted to multiple light sensing units, the image sensing devices disclosed by the above embodiments can adjust the luminous flux emitted into a single light sensing unit to achieve more precise operation. Moreover, the image sensing devices disclosed by the above embodiments can acquire image information with a high dynamic range in one image sensing procedure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An image sensing device, for sensing pixel data of a plurality of pixels in an image, comprising:
a substrate;
a plurality of light sensing units, each of the plurality of light sensing units being formed in the substrate and corresponding to one of the plurality of pixels; and
a plurality of pixel-level auto-light attenuators, each of the plurality of pixel-level light attenuators corresponding to one of the plurality of light sensing units and comprising:
a transparent dielectric layer, formed on the corresponding light sensing unit; and
an electronic-chromic layer, formed on the transparent dielectric layer.

2. The image sensing device of claim 1, wherein each of the plurality of light sensing units senses the luminous flux for generating a voltage corresponding to the pixel data of the corresponded pixel, and the electronic-chromic layer of each of the plurality of pixel-level auto light attenuators automatically adjusts the luminous flux emitted into the corresponded light sensing unit according to an electric field generated by the voltage of the corresponding light sensing unit.

3. The image sensing device of claim 2, wherein the transparency of the electronic-chromic layer is inversely proportional to the intensity of the electric field.

4. The image sensing device of claim 1, wherein the transparent dielectric layer is a filter corresponding to a specific color.

5. The image sensing device of claim 4, wherein the filter is printed on the light sensing unit.

6. The image sensing device of claim 1, further comprising a filter corresponding to a specific color formed on the electronic-chromic layer.

7. The image sensing device of claim 6, wherein the filter is printed on the electronic-chromic layer.

8. An image sensing device, for sensing pixel data of a plurality of pixels in an image, comprising:
a substrate;
a plurality of light sensing units, each of the plurality of light sensing units being buried in the substrate and corresponding to one of the plurality of pixels; and
a plurality of pixel-level auto light attenuators, each of the plurality of pixel-level auto light attenuators corresponding to one of the plurality of light sensing units and comprising:
a switch, coupled between the corresponding light sensing unit and a reset voltage; and
a doped layer, formed on the corresponding light sensing unit and doped with electronic-chromic materials.

9. The image sensing device of claim 8, wherein each of the plurality of light sensing units senses the luminous flux for generating a voltage corresponding to the pixel data of the corresponded pixel, and the doped layer of each of the plurality of pixel-level auto light attenuators automatically adjusts the luminous flux emitted into the corresponding light sensing unit according to an electric field generated by the voltage of the corresponding light sensing unit.

10. The image sensing device of claim 8, wherein the switch of each of the pixel-level auto light attenuators resets the voltage generated by the corresponding light sensing unit to the reset voltage after the image sensing device senses the pixel data.

11. The image sensing device of claim 8, wherein the electronic-chromic materials are trivalent electronic-chromic materials.

12. The image sensing device of claim 9, wherein the transparency of the doped layer is proportional to the intensity of the electric field.

13. An image sensing device, for sensing pixel data of a plurality of pixels in an image, comprising:
a substrate;
a plurality of light sensing units, each of the plurality of light sensing units being formed in the substrate and corresponding to one of the plurality of pixels; and
a plurality of pixel-level auto light attenuators, each of the plurality of pixel-level auto light attenuators comprising:
a micro-electro-mechanical (MEM) unit, formed on the corresponding light sensing unit, for adjusting the luminous flux emitted into the corresponding light sensing unit.

14. The image sensing device of claim 13, wherein each of the plurality of light sensing units senses the luminous flux for generating a voltage corresponding to the pixel data of the corresponding pixel, and the micro-electro-mechanical unit of each of the plurality of pixel-level auto light attenuators automatically adjusts the luminous flux emitted into the corresponding light sensing unit according to an electric field generated by the voltage of the corresponding light sensing unit.

15. The image sensing device of claim 13, wherein the micro-electro-mechanical unit comprises:
a conductive flexible membrane, covering the corresponding light sensing unit, wherein an end of the conductive flexible membrane is fixed to the corresponding light sensing unit; and
a switch, coupled to a reset voltage, the conductive flexible membrane and the corresponding light sensing unit.

16. The image sensing device of claim 15, wherein the conductive flexible membrane is formed on the corresponding light sensing unit with a deposition (sputtering) method.

17. The image sensing device of claim 15, wherein the conductive flexible membrane is a gold membrane.

18. The image sensing device of claim 14, wherein the micro-electro-mechanical unit reduces the luminous flux emitted into the corresponding light sensing unit when the voltage decreases.

19. An image sensing device, for sensing pixel data of a plurality of pixels in an image, comprising:
a substrate;
a plurality of light sensing units, each of the plurality of light sensing units being formed in the substrate and corresponding to one of the plurality of pixels; and
a plurality of pixel-level auto-light attenuators, each of the plurality of pixel-level light attenuators corresponding to one of the plurality of light sensing units for automatically adjusting the luminous flux emitted into the corresponding light sensing unit according to an electric field generated by the voltage of the corresponding light sensing unit.
